(19) United States
(12) Patent Application Publication
(10) Pub. No.: US 2012/0139529 A1
(43) Pub. Date: Jun. 7, 2012

(54) READOUT APPARATUS FOR CURRENT TYPE TOUCH PANEL

(75) Inventors: Kai-Lan Chuang, Tainan County (TW); Guo-Ming Lee, Tainan County (TW); Ying-Lieh Chen, Tainan County (TW)

(73) Assignee: HIMAX TECHNOLOGIES LIMITED, Tainan City (TW)

(21) Appl. No.: 13/370,219

(22) Filed: Feb. 9, 2012

Related U.S. Application Data
(62) Division of application No. 12/540,895, filed on Aug. 13, 2009.

(51) Int. Cl. G01R 11/04

(52) U.S. Cl. 324/157

(57) ABSTRACT

A readout apparatus for a current type touch panel is provided. The readout apparatus includes a current-to-voltage converter, a voltage gain unit and an analog-to-digital converter (ADC). The current-to-voltage converter converts a sensing current of the current type touch panel to a sensing voltage. The current-to-voltage converter includes a resistor and a current mirror. The resistor has a first end and a second end. The current mirror has a master current end and a slave current end. An input end of the voltage gain unit is coupled to an output end of the current-to-voltage converter for receiving the sensing voltage. An input end of the ADC is coupled to an output end of the voltage gain unit. An output end of the ADC generates a digital code.

### CROSS-REFERENCE TO RELATED APPLICATION

This application is a divisional of and claims the priority benefit of U.S. application Ser. No. 12/540,895, filed on Aug. 13, 2009, now pending. The entirety of the above-mentioned patent application is hereby incorporated by reference herein and made a part of this specification.

### BACKGROUND OF THE INVENTION

1. Field of the Invention

The present invention relates to a touch panel, and more particularly, to a readout apparatus for a current type touch panel.

2. Description of Related Art

Following the vigorous development of electronic technology and popularization of wireless communication and network, various electronic devices are becoming more and more indispensable in people's lives. However, common input/output (I/O) interfaces, such as keyboards or mouses, are difficult to operate. In contrast, touch panels are an intuitive and simple I/O interface. Therefore, touch panels are often used as a man-machine interface for execution of various control functions.

In general, touch panels include resistive touch panels, optical touch panels, capacitive touch panels, and so on. The touch panels can also be classified into a current type touch panel and a charge type touch panel in terms of its readout means. FIG. 1 illustrates a current type touch panel and a conventional readout circuit. Multiple scan lines of the touch panel 110 are driven by a gate driver 130, and multiple sensor lines of the touch panel 110 are coupled to a readout circuit 140. A pixel layout of the conventional current type touch panel is shown in FIG. 1. Each pixel includes a switch SW1 and a photo transistor PT.

When a bias voltage VBIAS is higher than the voltage of a node A and the gate driver 130 turns the switch SW1 on through the scan lines, because the photo transistors PT are in a forward-bias state, a sensing current Is will flow to the sensor lines through the photo transistors PT and the switch SW1. Intensity of the light radiated to the photo transistors PT can affect the value of the sensing currents Is. That is, by using the readout circuit 140 to detect the value and difference of the sensing currents Is on each of the sensor lines, it can be determined whether there is a shielding object over a corresponding area of the touch panel 110 (i.e., whether there is a foreign object touching the touch panel 110). The readout circuit 140 transmits the detecting result to an image processing circuit 150 in digital codes. The image processing circuit 150 then determines the touching area based on the digital codes provided by the readout circuit 140.

The conventional readout circuit 140 employs an integrator (i.e., an operational amplifier 141 and a feedback capacitor 142) to convert the sensing current Is to a corresponding voltage. The voltage is then converted to a corresponding digital code by an analog-to-digital converter (ADC) 143. Finally, the image processing circuit 150 determines the touching area based on the digital code. However, because the integrator is used in the readout operation for the touch panel, if the sensing current Is is too large, the output of the integrator may be in saturation. In order to avoid the saturation of the output of the integrator, the feedback capacitor (or referred to as integrator capacitor) 142 must increase in capacitance (i.e., increase the size) accordingly. Since each sensor line of the touch panel 110 requires an integrator, the chip size of the readout circuit 140 can be very large.

### SUMMARY OF THE INVENTION

The present invention provides a readout apparatus for a current type touch panel. The readout apparatus includes a current-to-voltage converter, a voltage gain unit, and an analog-to-digital converter (ADC). The current-to-voltage converter converts a sensing current of the current type touch panel to a sensing voltage. The voltage gain unit has an input end coupled to an output end of the current-to-voltage converter for receiving the sensing voltage. The ADC has an input end coupled to an output end of the voltage gain unit. An output end of the ADC is used to generate a digital code. The current-to-voltage converter includes a resistor and a current mirror.

The resistor has a first end for receiving a first reference voltage and a second end coupled to the input end of the voltage gain unit. The current mirror has a master current end for receiving the sensing current and a slave current end coupled to the second end of the resistor.

In view of the foregoing, the present invention provides a readout apparatus for a current type touch panel which reads out the sensing current of the touch panel using a current-to-voltage converter and the voltage gain unit (e.g. an inverting amplifier or a non-inverting amplifier). Therefore, the present readout apparatus can avoid the use of integrator capacitor, thus reducing the chip size.

In order to make the aforementioned and other features and advantages of the present invention more comprehensible, embodiments accompanied with figures are described in detail below.

### BRIEF DESCRIPTION OF THE DRAWINGS

FIG. 1 illustrates a current type touch panel and a conventional readout circuit.

FIG. 2 illustrates a circuit diagram of a readout apparatus for a current type touch panel according to one embodiment of the present invention.

FIG. 3 illustrates a circuit diagram of a readout apparatus for a current type touch panel according to a first embodiment of the present invention.

FIG. 4 illustrates a circuit diagram of a readout apparatus for a current type touch panel according to a second embodiment of the present invention.

FIG. 5 illustrates a circuit diagram of a voltage gain unit of FIG. 2 according to a third embodiment of the present invention.

FIG. 6 illustrates a circuit diagram of a readout apparatus for a current type touch panel according to a fourth embodiment of the present invention.

FIG. 7 illustrates a circuit diagram of a current-to-voltage converter of FIG. 2 according to a fifth embodiment of the present invention.

FIG. 8 illustrates a circuit diagram of a current-to-voltage converter of FIG. 2 according to a first embodiment of the present invention.

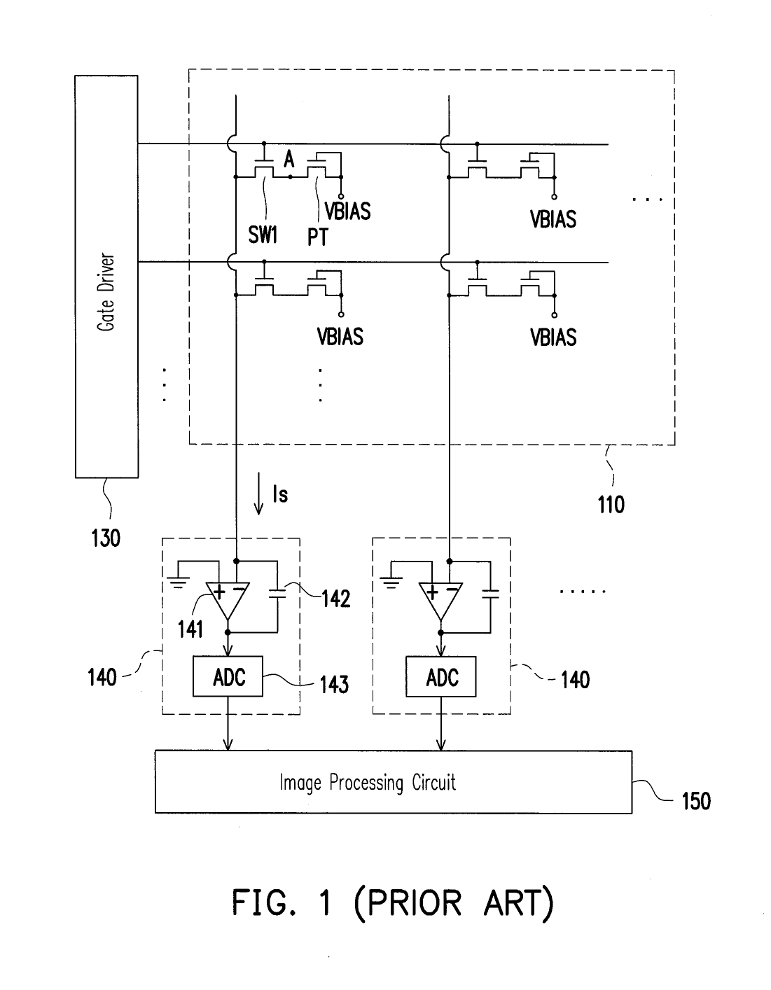

### DESCRIPTION OF THE EMBODIMENTS

The principle and application of the present readout apparatus will now be described in conjunction with embodiments in connection with a photo current type touch panel 110. It should be noted, however, that the present invention should not be regarded as limited to the embodiments set forth herein. Rather, the present readout apparatus could be used in any current type touch panel without departing from the spirit and scope of the present invention.

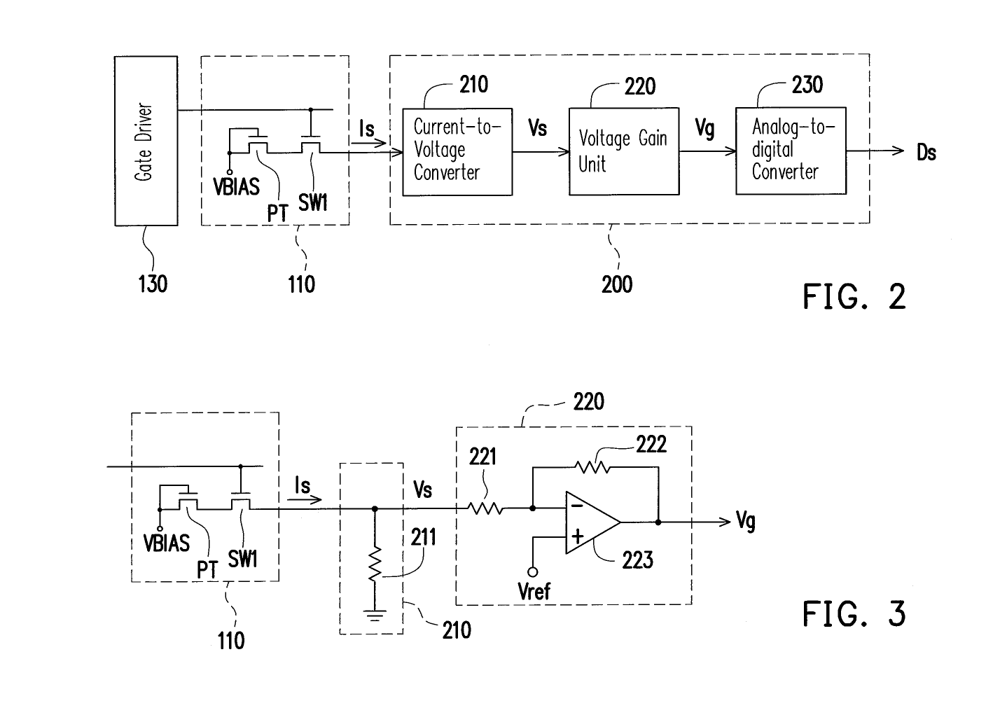

FIG. 2 illustrates a circuit diagram of a readout apparatus for a current type touch panel according to one embodiment of the present invention. The readout apparatus 200 includes a current-to-voltage converter 210, a voltage gain unit 220, and an analog-to-digital converter (ADC) 230. The current-to-voltage converter 210 converts a sensing current Is of the current type touch panel 110 to a sensing voltage Vs. An input end of the voltage gain unit 220 is coupled to an output end of the current-to-voltage converter 210 for receiving the sensing voltage Vs. After gaining or amplifying the sensing voltage Vs, the voltage gain unit 220 outputs the corresponding gained voltage Vg to the ADC 230. The voltage gain unit 220 may be, for example, an inverting amplifier or a non-inverting amplifier, which will be described hereinafter in greater detail.

An input end of the ADC 230 is coupled to an output end of the voltage gain unit 220. The ADC 230 converts the gained voltage Vg to a corresponding digital code Ds. The digital code Ds may be provided to a subsequent circuit (e.g., an image processing circuit 150) for further data processing to determine a touching area on the touch panel 110.

FIG. 3 illustrates a circuit diagram of a readout apparatus for a current type touch panel according to a first embodiment of the present invention. Referring to FIG. 3, the voltage gain unit 220 is implemented as an inverting amplifier. The inverting amplifier includes a resistor 221, a resistor 222, and an operational amplifier 223. The resistor 221 has a first end used as an input end of the inverting amplifier, and a second end coupled to a first input end of the operational amplifier 223. First and second ends of the resistor 222 are coupled to the first input end and an output end of the operational amplifier 223, respectively. A second input end of the operational amplifier 223 receives a third reference voltage Vref and the output end of the operational amplifier 223 is used as an output end of the inverting amplifier. In the present embodiment, the first input end of the operational amplifier 223 is an inverting input, while the second input end of the operational amplifier 223 is a non-inverting input. In addition, the level of the reference voltage Vref can be varied in various embodiments based on actual requirements. For example, the reference voltage Vref can be set as the ground voltage (i.e., 0 V), a band-gap voltage, +5V voltage, or another fixed voltage. In the present embodiment, the reference voltage Vref is set as a half of the level of a system voltage VDDA (i.e., VDDA/2).

The current-to-voltage converter 210 shown in FIG. 3 includes a resistor 211. The resistor 211 has a first end for receiving the sensing current Is. The first end of the resistor 211 is coupled to the input end (i.e., the first end of the resistor 221) of the inverting amplifier. A second end of the resistor 211 is coupled to a reference voltage (e.g., a ground voltage). The sensing current Is provided by the touch panel 110 flows through the resistor 211 thus generating a sensing voltage Vs at the first end of the resistor 211. If the change in the sensing current Is is very small, the resistance of the resistors 211, 221 and 222 can be increased in order to be able to distinguish changes in the gained voltage Vg. The resistors 211, 221 and 222 shown in FIG. 3 are fixed resistors. It is noted, however, that the resistors 211, 221 and/or 222 may also be implemented as variable resistors based on actual requirements for different touch panels with different characteristics.

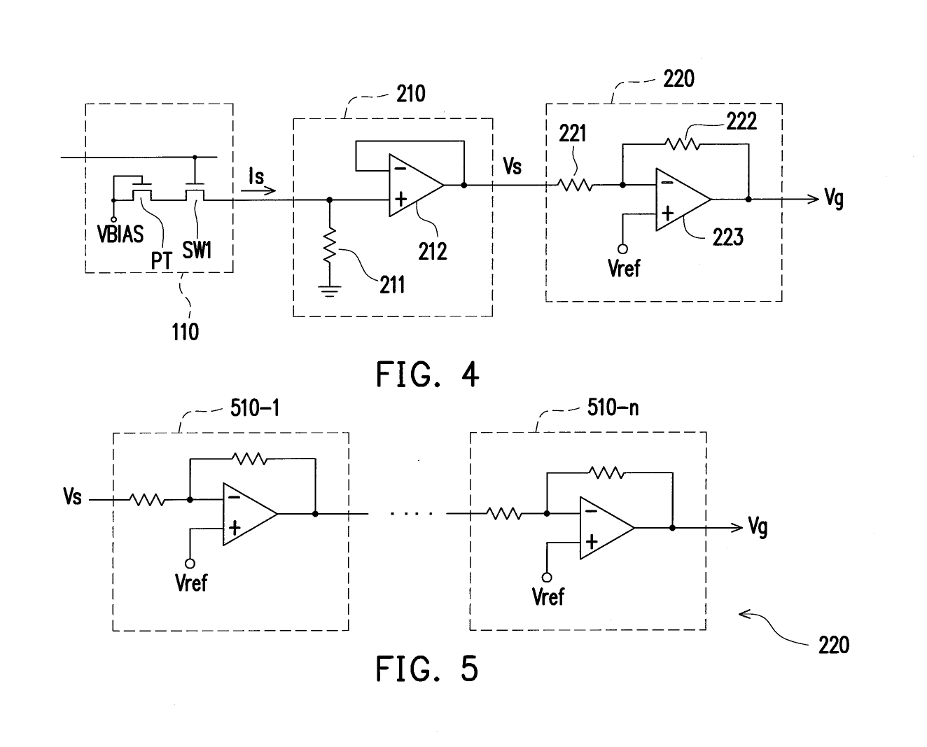

FIG. 4 illustrates a circuit diagram of a readout apparatus for a current type touch panel according to a second embodiment of the present invention. The second embodiment is similar to the embodiment illustrated in FIG. 3 except for the current-to-voltage converter 210, and the description of those same components is not repeated herein. Referring to FIG. 4, the current-to-voltage converter 210 includes the resistor 211 and a unity gain amplifier. In the present embodiment, the unity gain amplifier is implemented as an operational amplifier 212. The operational amplifier 212 has a first input end coupled to the first end of the resistor 211, and a second input end coupled to an output end of the operational amplifier 212. The output end of the operational amplifier 212 is coupled to the input end of the inverting amplifier (i.e., the first end of the resistor 221). In the present embodiment, the first input end of the operational amplifier 212 is a non-inverting input, while the second input end of the operational amplifier 212 is an inverting input. With the provision of the unity gain amplifier in the current-to-voltage converter 210, the loading effect on the sensing voltage Vs can be avoid.

If the change in the sensing current Is is very small, besides increasing the resistance of the resistors 211, 221 and 222 shown in FIG. 3 and FIG. 4, more inverting amplifiers can also be series-connected in the voltage gain unit 220 for increasing the gain of the voltage gain unit 220 in order to be able to distinguish changes in the gained voltage Vg. For example, a circuit diagram of a voltage gain unit 220 of FIG. 2 according to a third embodiment of the present invention is illustrated in FIG. 5.

Referring to FIG. 5, the inverting amplifier (voltage gain unit 220) includes n inverting amplifier circuits 510-1˜510-n. These inverting amplifier circuits 510-1˜510-n are connected in series to form an amplifier chain such that an input end of a first inverting amplifier circuit 510-1 of the amplifier chain is coupled to the output end of the current-to-voltage converter 210 for receiving the sensing voltage Vs, and an output end of a last inverting amplifier circuit 510-n of the amplifier chain is coupled to the input end of the ADC 230. The implementation of the inverting amplifier circuits 510-1˜510-n can be similar to that of the inverting amplifier of FIG. 3 and therefore the relevant description is not repeated herein. Since the multiple inverting amplifiers (i.e., the inverting amplifier circuits 510-1˜510-n) are series-connected in the voltage gain unit 220, the gain of the voltage gain unit 220 can be increased.

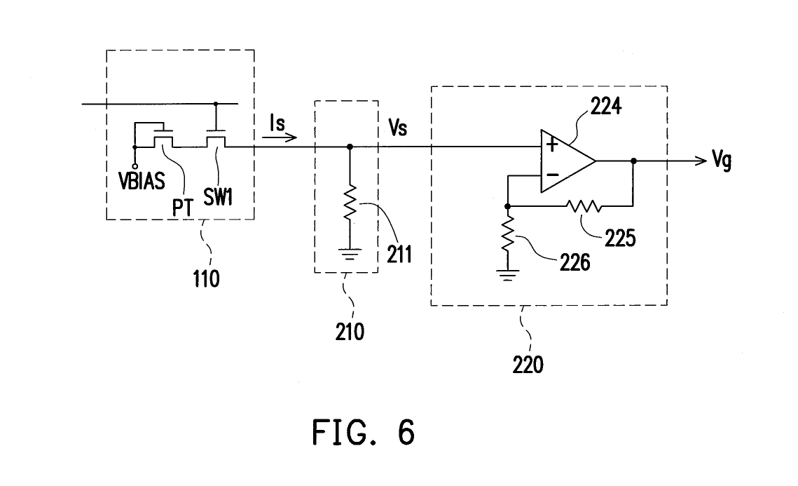

FIG. 6 illustrates a circuit diagram of a readout apparatus for a current type touch panel according to a fourth embodiment of the present invention. The fourth embodiment is similar to the embodiment illustrated in FIG. 3 except that the voltage gain unit 220 of FIG. 6 is implemented as a non-inverting amplifier, and the description of those same components is not repeated herein. Referring to FIG. 6, the non-inverting amplifier includes an operational amplifier 224, a resistor 225, and a resistor 226. A first input end of the operational amplifier 224 is coupled to the output end of the current-to-voltage converter 210, and an output end of the operational amplifier 224 outputs the gained voltage Vg to the input end of the ADC 230. A first end of the resistor 226 is coupled to a second input end of the operational amplifier 224, and a second end of the resistor 226 receives a reference voltage (e.g., a ground voltage).

First and second ends of the resistor 225 are coupled to the second input end and the output end of the operational amplifier 224, respectively. In the present embodiment, the first input end of the operational amplifier 224 is a non-inverting input, while the second input end of the operational amplifier 224 is an inverting input. In another embodiment, an inverter (not shown) may be disposed between the voltage gain unit 220 of FIG. 6 and the ADC 230 according to design requirements.

It is noted that the current-to-voltage converter 210 of FIG. 6 can be implemented in any manners based on actual requirements. For example, the current-to-voltage converter 210 can be implemented as a resistor and a current mirror in addition to the implementation illustrated in FIG. 3 and FIG. 4. In another embodiment, the non-inverting amplifier in the voltage gain unit 220 comprises a plurality of non-inverting amplifier circuits connected in series to form an amplifier chain. An input end of a first non-inverting amplifier circuit of the amplifier chain is coupled to the output end of the current-to-voltage converter 210, and an output end of a last non-inverting amplifier circuit of the amplifier chain is coupled to the input end of the ADC 230.

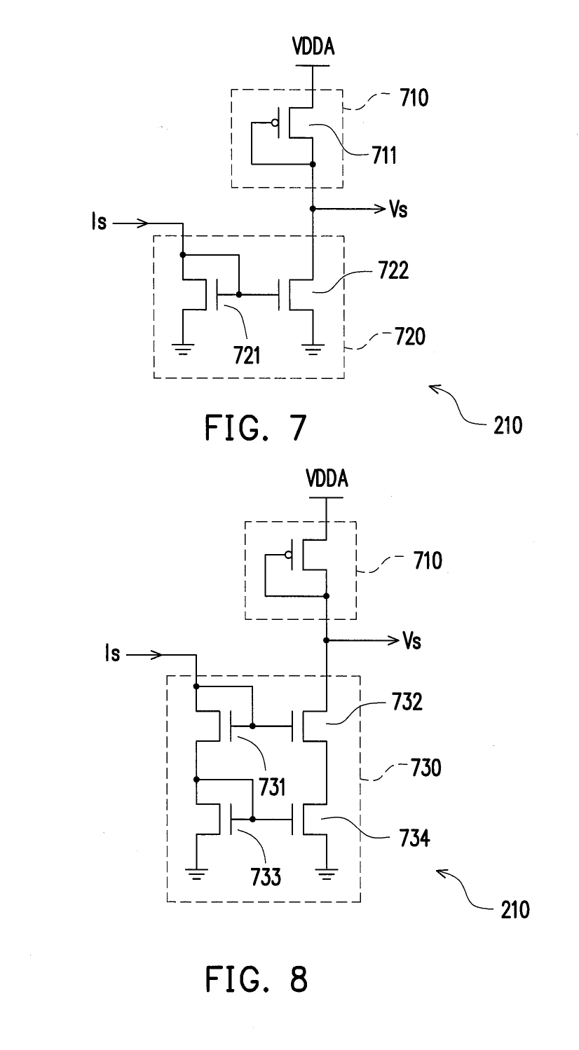

FIG. 7 illustrates a circuit diagram of a current-to-voltage converter 210 of FIG. 2 according to a fifth embodiment of the present invention. The current-to-voltage converter 210 includes a resistor 710 and a current mirror 720. The resistor 710 has a first end for receiving a first reference voltage (e.g., the system voltage VDDA), and a second end coupled to the input end of the voltage gain unit 220. In the present embodiment, the resistor 710 is implemented as a P channel metal oxide semiconductors (PMOS) transistor 711 to reduce the chip area occupied by the resistor 710. A first end (e.g., the source) of the transistor 711 receives the system voltage

VDDA, and a second end (e.g., the drain) and a control end (e.g., the gate) of the transistor 711 are coupled to the input end of the voltage gain unit 220.

A master current end of the current mirror 720 receives the sensing current Is and a slave current end of the current mirror 720 is coupled to the second end of the resistor 710. The current mirror 720 can amplify a weak sensing current Is by setting a suitable current magnification between the master and slave current ends of the current mirror 720. The amplified sensing current is converted to a sensing voltage Vs through the resistor 710. As such, when the photo transistors PT are radiated by strong and weak lights, the amplitude of changes in the obtained sensing voltage Vs can be increased thus increasing the capability of distinguishing the sensing voltage Vs. The sensing voltage Vs is then amplified secondarily by the inverting amplifier/non-inverting amplifier (i.e., the voltage gain unit 220) to the gained voltage Vg for facilitating the processing by subsequent circuits.

Here, the current mirror 720 includes a first transistor 721 and a second transistor 722. In the present embodiment, the transistors 721, 722 are implemented as N channel metal oxide semiconductors (NMOS) transistors. A first end (e.g., the drain) of the transistor 721 is used as the master current end of the current mirror 720, a second end (e.g., the source) of the transistor 721 receives a second reference voltage (e.g., a ground voltage), and a control end (e.g., the gate) of the transistor 721 is coupled to the first end of the transistor 721. A first end of the transistor 722 is used as the slave current end of the current mirror 720, a second end of the transistor 722 receives the second reference voltage (the ground voltage), and a control end of the transistor 722 is coupled to the control end of the transistor 721. The current magnification between the master current end and the slave current end can be set by determining the aspect ratios of the transistors 721 and 722.

FIG. 8 illustrates a circuit diagram of a current-to-voltage converter 210 of FIG. 2 according to a sixth embodiment of the present invention. The sixth embodiment is similar to the embodiment illustrated in FIG. 7 except that a current mirror 730 is used in FIG. 8 in lieu of the above-described current mirror 720, and the description of those same components is not repeated herein. The current mirror 730 includes a first transistor 731, a second transistor 732, a third transistor 733, and a fourth transistor 734. A first end (e.g., the drain) of the transistor 731 is used as the master current end of the current mirror 730, and a control end (e.g., the gate) of the transistor 731 is coupled to the first end of the transistor 731. A first end (e.g., the drain) of the transistor 732 is used as the slave current end of the current mirror 730, and a control end (e.g., the gate) of the transistor 732 is coupled to the control end of the transistor 731. A first end (e.g., the drain) of the transistor 733 is coupled to a second end (e.g., the source) of the transistor 731, a second end (e.g., the source) of the transistor 733 receives a reference voltage (e.g., a ground voltage), and a control end (e.g., the gate) of the transistor 733 is coupled to the first end of the transistor 733. A first end (e.g., the drain) of the transistor 734 is coupled to a second end (e.g., the source) of the transistor 732, a second end (e.g., the source) of the transistor 734 receives the reference voltage (the ground voltage), and a control end (e.g., the gate) of the transistor 734 is coupled to the control end of the transistor 733.

In summary, when the switch SW1 of the touch panel 110 is turned off, the sensor lines have no sensing current Is flowing therethrough and therefore the gained voltage Vg is minimum at this time. At this time, the system can obtain a first digital value of the gained voltage Vg using the ADC 230. When the switch SW1 of the touch panel 110 is turned on, a sensing current Is flows through the sensor lines and the gained voltage Vg is increased. At this time, the system can amplify and convert the sensing current Is to a gained voltage Vg using the current-to-analog converter 210 and the inverting amplifier (or non-inverting amplifier), and obtain a second digital value of the gained voltage Vg using the ADC 230. The system then computes the difference between the second digital value and the first digital value. Since the sensing current Is generated by the photo transistor PT when radiated by a strong light is different from the sensing current Is generated by the photo transistor PT when radiated by a weak light, the difference between the second digital value and the first digital value also varies and the touching area can thereby be determined.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A readout apparatus for a current type touch panel, comprising:
a current-to-voltage converter adapted to convert a sensing current of a current type touch panel to a sensing voltage;
a voltage gain unit having an input end coupled to an output end of the current-to-voltage converter for receiving the sensing voltage; and
an analog-to-digital converter (ADC) having an input end coupled to an output end of the voltage gain unit, an output end of the ADC adapted to generate a digital code,
wherein the current-to-voltage converter comprises:
a resistor having a first end for receiving a first reference voltage and a second end coupled to the input end of the voltage gain unit; and
a current mirror having a master current end for receiving the sensing current and a slave current end coupled to the second end of the resistor.

2. The readout apparatus for the current type touch panel according to claim 1, wherein the resistor is a transistor having a first end for receiving the first reference voltage, and a second end and a control end of the transistor are coupled to the input end of the voltage gain unit.

3. The readout apparatus for the current type touch panel according to claim 1, wherein the current mirror comprises:
a first transistor having a first end used as the master current end of the current mirror and a second end for receiving a second reference voltage, a control end of the first transistor coupled to the first end of the first transistor; and
a second transistor having a first end used as the slave current end of the current mirror and a second end for receiving the second reference voltage, a control end of the second transistor coupled to the control end of the first transistor.

4. The readout apparatus for the current type touch panel according to claim 3, wherein the first reference voltage is a system voltage, and the second reference voltage is a ground voltage.

5. The readout apparatus for the current type touch panel according to claim 1, wherein the current mirror comprises:
a first transistor having a first end used as the master current end of the current mirror and a control end coupled to the first end of the first transistor;
a second transistor having a first end used as the slave current end of the current mirror and a control end of the second transistor coupled to the control end of the first transistor;
a third transistor having a first end coupled to a second end of the first transistor and a second end for receiving a second reference voltage, a control end of the third transistor coupled to the first end of the third transistor; and
a fourth transistor having a first end coupled to a second end of the second transistor and a second end for receiving the second reference voltage, a control end of the fourth transistor coupled to the control end of the third transistor.

6. The readout apparatus for the current type touch panel according to claim 1, wherein the voltage gain unit is implemented as a non-inverting amplifier.

7. The readout apparatus for the current type touch panel according to claim 6, wherein the non-inverting amplifier comprises:
an operational amplifier having a first input end used as the input end of the non-inverting amplifier and an output end used as the output end of the non-inverting amplifier;
a first resistor having a first end coupled to a second input end of the operational amplifier and a second end for receiving a reference voltage; and
a second resistor having a first end and a second end coupled to the second input end and the output end of the operational amplifier, respectively.

8. The readout apparatus for the current type touch panel according to claim 6, wherein the non-inverting amplifier comprises a plurality of non-inverting amplifier circuits connected in series to form an amplifier chain, an input end of a first non-inverting amplifier circuit of the amplifier chain is coupled to the output end of the current-to-voltage converter, and an output end of a last non-inverting amplifier circuit of the amplifier chain is coupled to the input end of the ADC.
